(19) United States
(12) Patent Application Publication
(10) Pub. No.: US 2025/0380512 A1
(43) Pub. Date: Dec. 11, 2025

(54) MULTI-FINGER MOS CIRCUIT, METHOD OF MANUFACTURING THE SAME, AND SYSTEM

(71) Applicant: TAIWAN SEMICONDUCTOR MANUFACTURING COMPANY, LTD., Hsinchu (TW)

(72) Inventors: Tung-Cheng CHANG, Hsinchu (TW); Chia-En HUANG, Hsinchu (TW); Chun-Ying LEE, Hsinchu (TW); Yen-Hsiang HUANG, Hsinchu (TW); Hui Pin FENG, Hsinchu (TW)

(21) Appl. No.: 18/737,113

(22) Filed: Jun. 7, 2024

(51) Int. Cl. H01L 27/02; H01L 21/8234; H01L 23/498

(52) U.S. Cl. CPC H10D 89/10; H01L 23/49844; H10D 84/0135; H10D 84/038

(57) ABSTRACT

An IC device includes an active region; a first conductive line extending in a first direction and corresponding to a first transistor, and a second conductive line corresponding to a second transistor, the first and second transistors connected in series and split into two or more nets; first gate structures connected to the first conductive line and corresponding to the first transistor; second gate structures connected to the second conductive line and corresponding to the second transistor, the second gate structures being equal in number to the first gate structures; and a first contact structure between a first one of the first gate structures and a first one of the second gate structures, and a second contact structure between a second one of the first gate structures and a second one of the second gate structures, the number of contact structures being equal to the number of nets.

### BACKGROUND

The semiconductor integrated circuit (IC) industry has produced a wide variety of devices to address issues in a number of different areas. The structure of device elements and routing of signal and power lines affect signal integrity and power consumption. As ICs have become smaller and more complex, the resistance of conductive lines within these devices have also changed, affecting the operating voltages of these devices and overall IC performance.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a layout diagram of a multi-transistor circuit having a series arrangement and split interconnections, in accordance with some embodiments.

FIGS. 2A-2D are schematic diagrams of multi-transistor circuits having series arrangements and split interconnections, in accordance with some embodiments.

FIG. 3 is a layout diagram of a multi-transistor circuit having a series arrangement and split interconnections, in accordance with some embodiments.

FIG. 4 is a layout diagram of a multi-transistor circuit having a series arrangement and split interconnections, in accordance with some embodiments.

FIG. 5 is a layout diagram of a multi-transistor circuit having a series arrangement and split interconnections, in accordance with some embodiments.

FIG. 6 is a flowchart of a method of manufacturing a semiconductor device, in accordance with some embodiments.

FIG. 7A is a flowchart of a method of generating a layout diagram, in accordance with some embodiments.

FIG. 7B is a method of fabricating a semiconductor device based on a layout diagram, in accordance with some embodiments.

FIG. 8 is a block diagram of an electronic design automation (EDA) system in accordance with some embodiments.

FIG. 9 is a block diagram of a semiconductor device manufacturing system, and an IC manufacturing flow associated therewith, in accordance with some embodiments.

### DETAILED DESCRIPTION

The following disclosure provides different embodiments, or examples, for implementing features of the provided subject matter. Specific examples of components, materials, values, steps, arrangements, or the like, are described below to simplify the present disclosure. These are, of course, merely examples and are not limiting. Other components, materials, values, steps, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Circuit performance is improved by circuit design and layout co-optimization. In an unoptimized circuit or layout, parasitic resistance and capacitance can degrade circuit performance in terms of speed and power consumption, e.g., in a circuit and layout in which interconnections of two series-connected MOS transistors go through excess vias and metal routing. In accordance with some embodiments, circuit design and layout co-optimization reduce parasitic resistance and capacitance of each net of a circuit to improve the performance of the circuit, relative to a device in which a circuit includes additional vias and/or metal routing. In some embodiments, circuit design and layout co-optimization improve the circuit performance in terms of speed by RC delay reduction, and reduce active power by reducing parasitic capacitance. In some embodiments, a fully staggered style layout helps to reduce an equivalent resistance of each path of a circuit that includes two series-connected MOS transistors. In some embodiments, first and second ones of two series-connected MOS transistors are staggered in the same group, the interconnections of the two MOS transistors are split, and excess vias and metal routing is avoided.

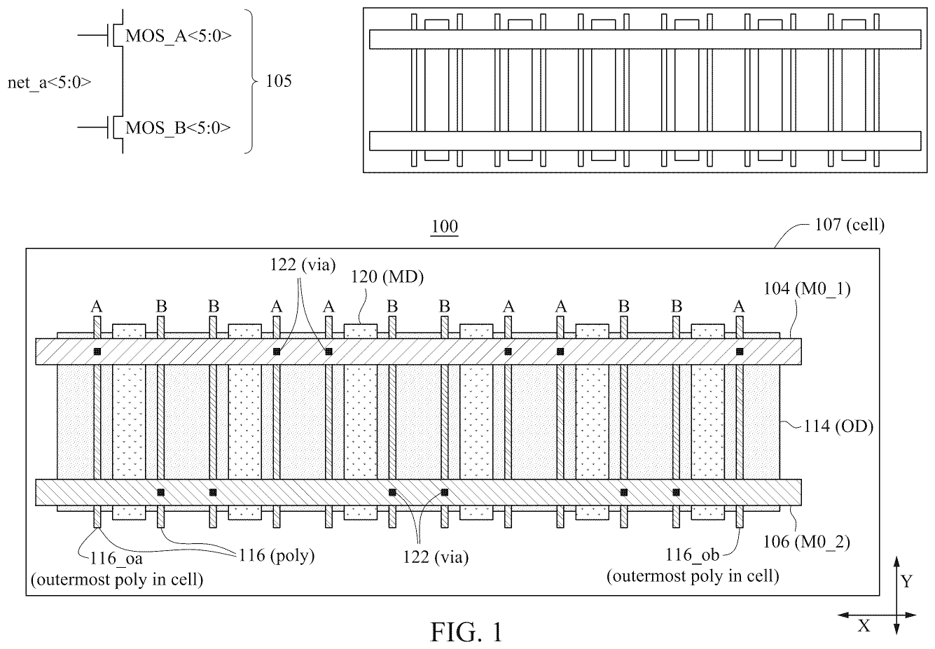

FIG. 1 is a diagram of a layout 100 of a multi-transistor circuit 105 having a series arrangement and split interconnections, in accordance with some embodiments.

In FIG. 1, the circuit 105 includes a first transistor MOS_A and a second transistor MOS_B. The first and second transistors MOS_A, MOS_B are connected in series. The first and second transistors MOS_A, MOS_B are metal oxide semiconductor (MOS) transistors, e.g., field effect transistors (FETs), FETs having fins (finFETs), or the like.

The layout 100 represents aspects of one cell 107. In the layout 100, a first conductive line 104 and a second conductive line 106 extend parallel to a first direction (X direction) in a first metal layer (MO) over a substrate (e.g., a semiconductor substrate). The first conductive line 104 is spaced apart from the second conductive line 106 in a second direction (Y direction). The first transistor MOS_A and the second transistor MOS_B correspond to an active region 114. The active region 114 is an oxide-defined (OD) region that extends parallel to the first direction (X direction) on the substrate. Each of the first and second transistors MOS_A, MOS_B has a number of conductive gate structures 116 (e.g., polysilicon or the like) that extend parallel to the second direction (Y direction) and correspond in number to a number of fingers of the first and second transistors MOS_A, MOS_B. A gate insulating film (e.g., a silicon oxide film) is interposed between the gate structures 116 and the active region 114. The gate structures 116 of the first transistor MOS_A (corresponding to fingers ‘A’ of the first transistor MOS_A) are connected to the first conductive line 104 by vias 122. The gate structures 116 of the second transistor MOS_B (corresponding to fingers ‘B’ of the second transistor MOS_B) are connected to the second conductive line 106 by vias 122.

In the layout 100, the first transistor MOS_A is a same conductivity type (e.g., NMOS or PMOS) as the second transistor MOS_B (e.g., NMOS or PMOS). The first and second active regions are provided having the same conductivity types, each extending in parallel to the first direction (X direction) and spaced apart in the second direction (Y direction), and underlying a corresponding one of the first conductive line 104 and the second conductive line 106. Correspondingly, the first transistor MOS_A is a same conductivity type as the second transistor MOS_B. For example, in an embodiment, a first active region is N-type and a second active region is N-type, and the first transistor MOS_A is NMOS and the second transistor MOS_B is NMOS. For another example, in an embodiment, a first active region is P-type and a second active region is P-type, and the first transistor MOS_A is PMOS and the second transistor MOS_B is PMOS.

In the layout 100, metal-to-diffusion (MD) contact structures 120 (which are in an MD layer on the active region) extend parallel to the second direction (Y direction) and are arranged between ‘A’ and ‘B’ fingers of the first and second transistors MOS_A, MOS_B. The contact structures 120 are interleaved among gate structures 116 of opposite ones of the first and second transistors MOS_A, MOS B along the active region 114. The contact structures 120 overlap the active region 114.

In the circuit 105, the first transistor MOS_A includes six fingers (MOS_A<5:0>) and the second transistor MOS_B includes six fingers (MOS_B<5:0>). The interconnections of MOS_A and MOS_B are split to six different nodes (corresponding to six contact structures 120 in the layout 100). Thus, the circuit 105 includes six nets (net_a<5:0>). The number of contact structures 120 is equal to the number of nets in the circuit 105. In some embodiments, the number of fingers in each of the first and second transistors MOS_A, MOS_B is greater than six or less than six and, correspondingly, the number of nets is greater than six or less than six. Thus, for example, in an embodiment, the number of fingers in each of the first and second transistors MOS_A, MOS_B is two and the number of nets is two.

In FIG. 1, the gate structures 116 (i.e., the fingers) of the first transistor MOS_A and the fingers of the second transistor MOS_B are fully staggered in a pattern ‘ABBA’ that repeats in the layout 100 (where ‘A’ is a finger of the first transistor MOS_A and ‘B’ is a finger of the second transistor MOS_B). In the layout 100, the pattern ‘ABBA’ repeats two times, such that the six fingers of the first transistor MOS_A (MOS_A<5:0>) and the six fingers of the second transistor MOS_B (MOS_B<5:0>) are arranged in an overall pattern of ‘ABBAABBAABBA’. Thus, in the cell represented by the layout 100, gate structure 116_oa and gate structure 116_ob are outermost ones of the twelve gate structures 116 of the first and second transistors MOS_A, MOS_B. Additionally, the outermost gate structures 116_oa, 116_ob both correspond to a same transistor. For example, in FIG. 1, the outermost gate structures 116_oa, 116_ob both correspond to the first transistor MOS_A (i.e., correspond to fingers ‘A’). In another embodiment, the outermost gate structures 116_oa, 116_ob both correspond to the second transistor MOS_B (or another transistor when more than two transistors are connected in series in the circuit 105).

Due to the fully staggered arrangement ‘ABBAABBAABBA’ of the fingers of the series-connected first and second transistors MOS_A and MOS_B, a connection structure of the circuit 105 is simplified in the layout 100 relative to an arrangement ‘AAAAAABBBBBB’ or an arrangement ‘AABBAABBAABB’ that would necessitate connecting the outermost fingers (an ‘A’ finger and a ‘B’ finger) using additional metal routing (e.g., in the first metal layer M0) and vias (e.g., vias in a via layer VD that is beneath the first metal layer M0 and above the MD layer). In some embodiments, one or more of the contact structures 120 is free of an electrical connection (e.g., free of a direct connection or via in the via layer VD directly over the MD layer) to an overlying metal layer (such as a first metal layer M0).

As described above, in the layout 100 of FIG. 1, interconnections of the first and second transistors MOS_A and MOS_B are made in the MD layer (i.e., using the contact structures 120 in the MD layer) thereby minimizing vias and metal routing in the first metal layer M0. The fully staggered style layout 100 of FIG. 1 decreases the overall equivalent resistance of the connection paths relative to a layout in which some or all fingers of two series-connected transistors are connected through a metal layer such as a first metal layer M0. Thus, the fully staggered style layout 100 of FIG. 1 reduces parasitic resistance and capacitance (RC) from vias and metal routing, improves circuit performance (speed) by reducing RC delays, and improves power consumption (i.e., reduces active power) by reducing parasitic capacitance relative to a layout in which a greater number of connections are made in, e.g., the M0 layer.

Also, nodes of net_a in the circuit 105 are each a different node. In the layout 100, the MD layer is used to connect the first and second transistors MOS_A, MOS_B. Correspondingly, each contact structure 120 is included in a different node. In contrast, if the fingers of the first and second transistors MOS_A, MOS_B were arranged as ‘AAAABBBB’ or ‘ABABABABABAB’ (instead of ‘ABBAABBAABBA’ in layout 100), then the net could not be split.

The fully staggered style layout 100 of FIG. 1 includes fingers of the first and second transistors MOS_A, MOS_B arranged with a pattern ABBA. The layout 100 can be extended to cases where first, second, and third transistors MOS_A, MOS_B, MOS_C are connected in series with a pattern ABCCBA, or first, second, third, and fourth transistors MOS_A, MOS_B, MOS_C, MOS_D are connected in series with a pattern ABCDDCBA. The layout 100 can be applied to all process nodes.

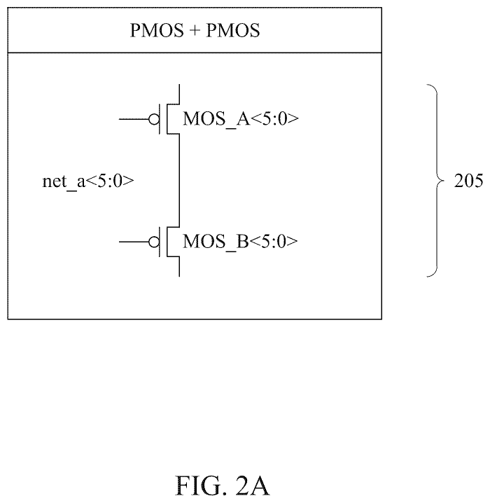

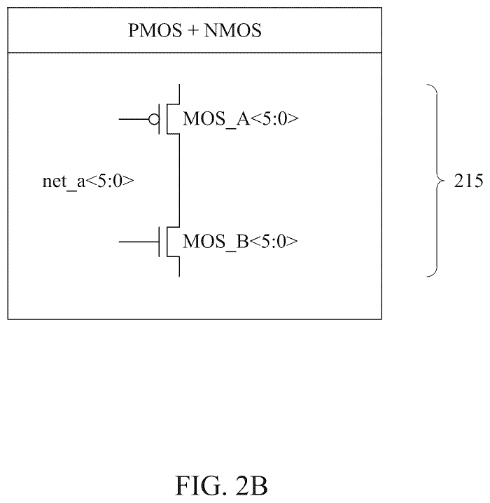

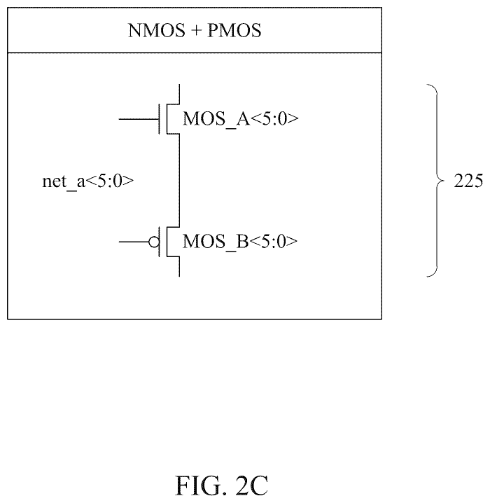

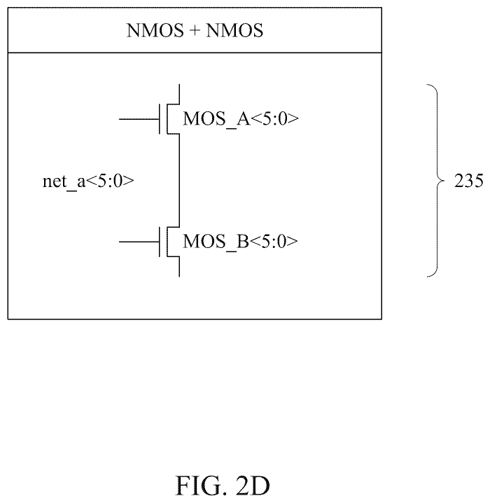

FIG. 2A is a schematic diagram of a multi-transistor circuit 205 having a series arrangement of two PMOS transistors having split interconnections. In FIG. 2A, the first transistor MOS_A is a PMOS transistor and the second transistor MOS_B is a PMOS transistor. In some embodiments, the circuit 205 of FIG. 2A is implemented using the layout 100 of FIG. 1.

FIG. 2B is a schematic diagram of a multi-transistor circuit 215 having a series arrangement of a PMOS transistor and an NMOS transistor having split interconnections. In FIG. 2B, the first transistor MOS_A is a PMOS transistor and the second transistor MOS_B is an NMOS transistor. In some embodiments, the circuit 215 of FIG. 2B is implemented using a modification of the layout 100 of FIG. 1 in which first and second active regions are provided, each extending in parallel to the first direction (X direction) and having different conductivity types.

FIG. 2C is a schematic diagram of a multi-transistor circuit 225 having a series arrangement of an NMOS transistor and a PMOS transistor having split interconnections. In FIG. 2C, the first transistor MOS_A is an NMOS transistor and the second transistor MOS_B is a PMOS transistor. In some embodiments, the circuit 225 of FIG. 2C is implemented using the layout 100 of FIG. 1.

FIG. 2D is a schematic diagram of a multi-transistor circuit 235 having a series arrangement of two NMOS transistors having split interconnections. In FIG. 2D, the first transistor MOS_A is an NMOS transistor and the second transistor MOS_B is an NMOS transistor. In some embodiments, the circuit 235 of FIG. 2D is implemented using a modification of the layout 100 of FIG. 1 in which first and second active regions are provided, each extending in parallel to the first direction (X direction) and having different conductivity types.

As described above, the layout 100 of FIG. 1 can be implemented for all combinations of PMOS and NMOS transistors as the first and second transistors MOS_A and MOS_B, i.e., for a first combination of PMOS transistor +PMOS transistor as the first and second transistors MOS_A and MOS_B (FIG. 2A), for a second combination of PMOS transistor+NMOS transistor (using first and second active regions) as the first and second transistors MOS_A and MOS_B (FIG. 2B), for a third combination of NMOS transistor+PMOS transistor (using first and second active regions) as the first and second transistors MOS_A and MOS_B (FIG. 2C), or for a fourth combination of NMOS transistor+NMOS transistor as the first and second transistors MOS_A and MOS_B (FIG. 2D).

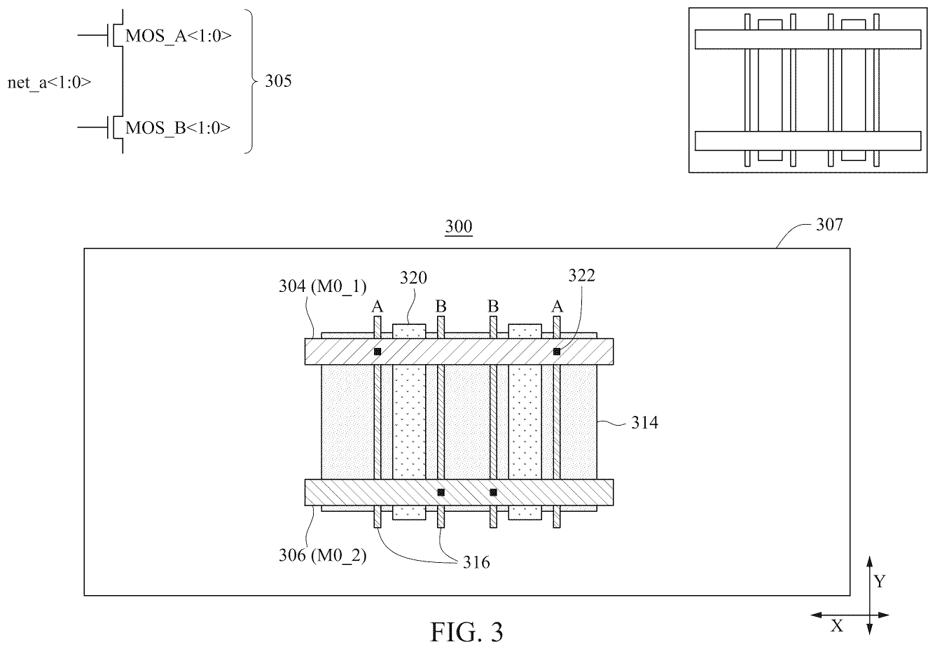

FIG. 3 is a diagram of a layout 300 of a multi-transistor circuit 305 having a series arrangement and split interconnection, in accordance with some embodiments.

In FIG. 3, the circuit 305 includes two nets (net_a<1:0>) for two transistors MOS_A, MOS_B connected in series, and interconnections of the first transistor MOS_A and the second transistor MOS_B are split. The first transistor MOS_A has two fingers (MOS_A<1:0>) and the second transistor MOS_B has two fingers (MOS_B<1:0>).

The layout 300 represents aspects of one cell 307. In the layout 300, a first conductive line 304 and a second conductive line 306 extend parallel to the first direction (X direction) in the first metal layer M0. The first conductive line 304 is spaced apart from the second conductive line 306 in the second direction (Y direction). The first transistor MOS_A and the second transistor MOS_B correspond to an active region 314. The active region 314 extends parallel to the first direction (X direction). Gate structures 316 of the first transistor MOS_A (corresponding to fingers ‘A’ of the first transistor MOS_A) are connected to the first conductive line 304 by vias 322 in the via layer VD. Gate structures 316 of the second transistor MOS_B (corresponding to fingers ‘B’ of the second transistor MOS_B) are connected to the second conductive line 306 by vias 322 in the via layer VD.

The first transistor MOS_A and the second transistor MOS_B have connections made by MD contact structures 320 in the MD layer. The contact structures 320 extend parallel to the second direction (Y direction) and overlap the active region 314.

In FIG. 3, the fingers of the first and second transistors MOS_A, MOS_B are fully staggered, as in FIG. 1. That is, the fingers of the first and second transistors MOS_A, MOS_B are laid out in a fully staggered style ‘ABBA’ in the layout 300 (where ‘A’ is a finger of the first transistor MOS_A and ‘B’ is a finger of the second transistor MOS_B).

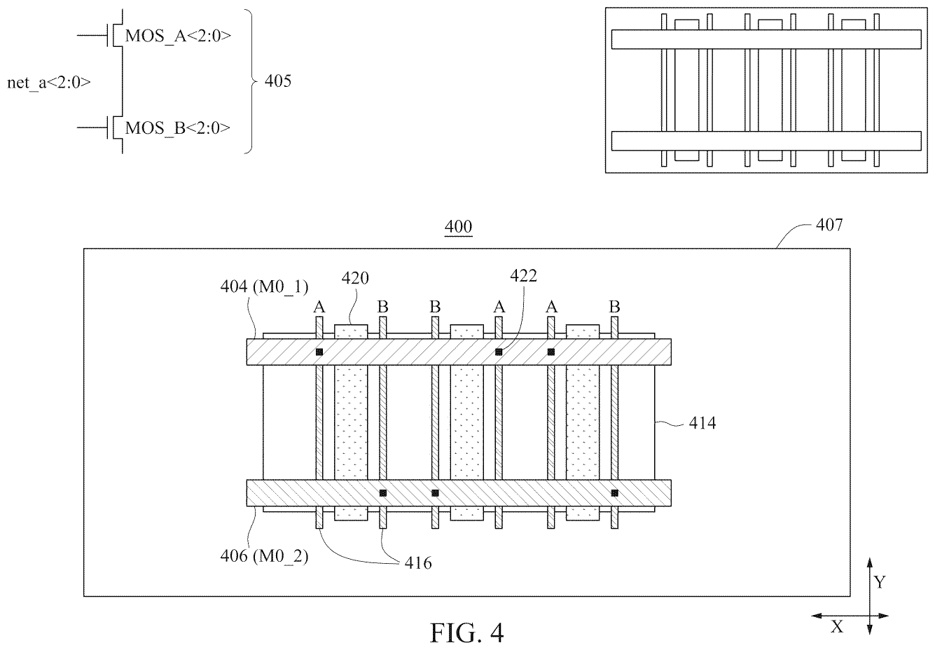

FIG. 4 is a diagram of a layout 400 of a multi-transistor circuit 405 having a series arrangement and split interconnection, in accordance with some embodiments.

In FIG. 4, the circuit 405 includes three nets (net_a<2:0>) for two transistors MOS_A, MOS_B connected in series, and interconnections of the first transistor MOS_A and the second transistor MOS_B are split. The first transistor MOS_A has three fingers (MOS_A<2:0>) and the second transistor MOS_B has three fingers (MOS_B<2:0>).

The layout 400 represents aspects of one cell 407. In the layout 400, a first conductive line 404 and a second conductive line 406 extend parallel to the first direction (X direction) in the first metal layer MO. The first conductive line 404 is spaced apart from the second conductive line 406 in the second direction (Y direction). The first transistor MOS_A and the second transistor MOS_B correspond to an active region 414. The active region 414 extends parallel to the first direction (X direction). Gate structures 416 of the first transistor MOS_A (corresponding to fingers ‘A’ of the first transistor MOS_A) are connected to the first conductive line 404 by vias 422 in the via layer VD. Gate structures 416 of the second transistor MOS_B (corresponding to fingers ‘B’ of the second transistor MOS_B) are connected to the second conductive line 406 by vias 422 in the via layer VD.

The first transistor MOS_A and the second transistor MOS_B have connections made by MD contact structures 420 in the MD layer. The contact structures 420 extend parallel to the second direction (Y direction) and overlap the active region 414.

In FIG. 4, the fingers of the first and second transistors MOS_A, MOS_B are fully staggered. That is, the fingers of the first and second transistors MOS_A, MOS_B are laid out in an arrangement ‘ABBA’ that partially repeats to form an overall pattern ‘ABBAAB’ in the layout 400 (where ‘A’ is a finger of the first transistor MOS_A and ‘B’ is a finger of the second transistor MOS_B). This structure avoids the need for additional via connections in manner similar to that described above in connection with FIG. 1.

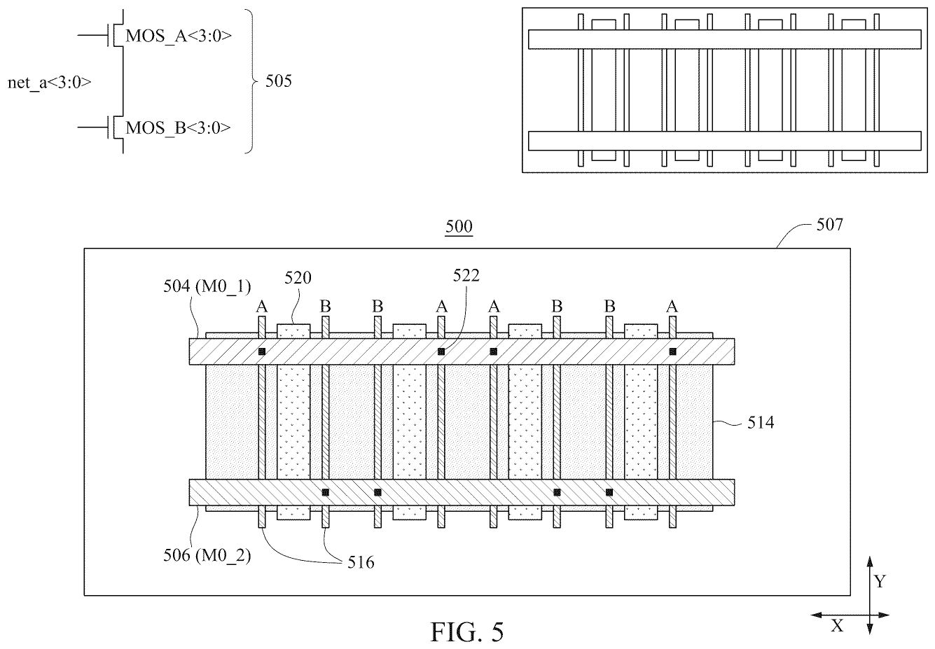

FIG. 5 is a diagram of a layout 500 of a multi-transistor circuit 505 having a series arrangement and split interconnection, in accordance with some embodiments.

In FIG. 5, the circuit 505 includes four nets (net_a<3:0>) for two transistors MOS_A, MOS_B connected in series, and interconnections of the first transistor MOS_A and the second transistor MOS_B are split. The first transistor MOS_A has four fingers (MOS_A<3:0>) and the second transistor MOS_B has four fingers (MOS_B<3:0>).

The layout 500 represents aspects of one cell 507. In the layout 500, a first conductive line 504 and a second conductive line 506 extend parallel to the first direction (X direction) in the first metal layer M0. The first conductive line 504 is spaced apart from the second conductive line 506 in the second direction (Y direction). The active region 514 extends parallel to the first direction (X direction). Gate structures 516 of the first transistor MOS_A (corresponding to fingers ‘A’ of the first transistor MOS_A) are connected to the first conductive line 504 by vias 522 in the via layer VD. Gate structures 516 of the second transistor MOS_B (corresponding to fingers ‘B’ of the second transistor MOS_B) are connected to the second conductive line 506 by vias 522 in the via layer VD.

The first transistor MOS_A and the second transistor MOS_B have connections made by MD contact structures 520 in the MD layer. The contact structures 520 extend parallel to the second direction (Y direction) and overlap the active region 514.

In FIG. 5, the fingers of the first and second transistors MOS_A, MOS_B are fully staggered. That is, the fingers of the first and second transistors MOS_A, MOS_B are laid out in a fully staggered style ‘ABBA’ that repeats in the layout 500 to form an overall pattern ‘ABBAABBA’ (where ‘A’ is a finger of the first transistor MOS_A and ‘B’ is a finger of the second transistor MOS_B).

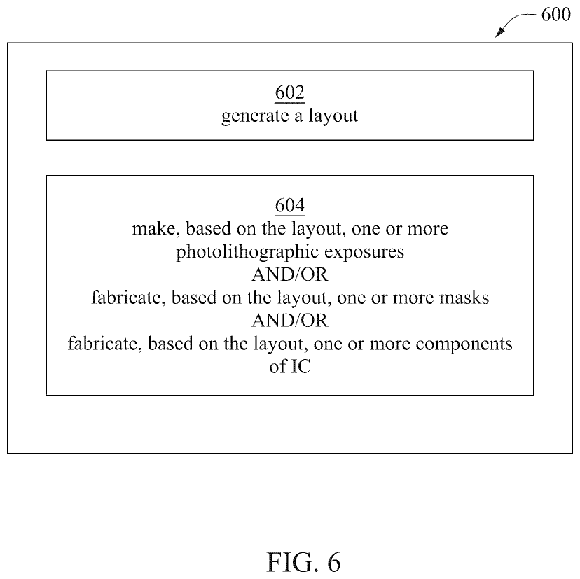

FIG. 6 is a flowchart of a method 600 of generating a layout, in accordance with some embodiments.

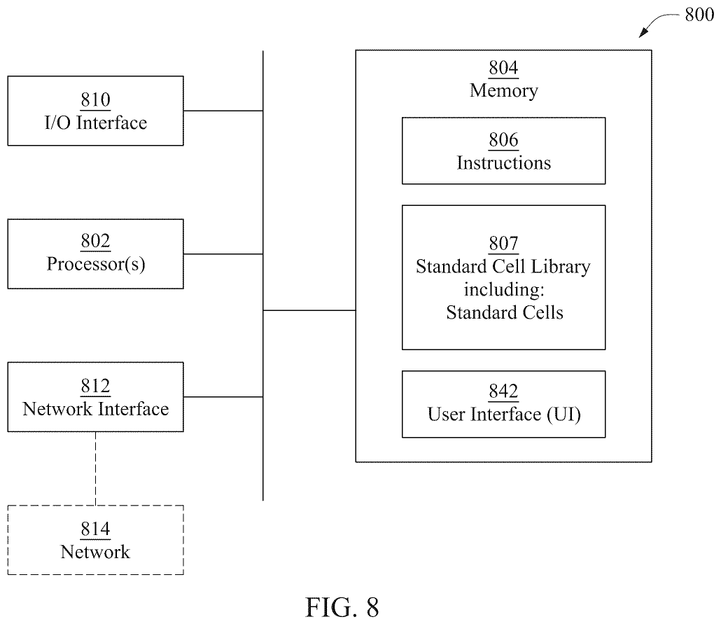

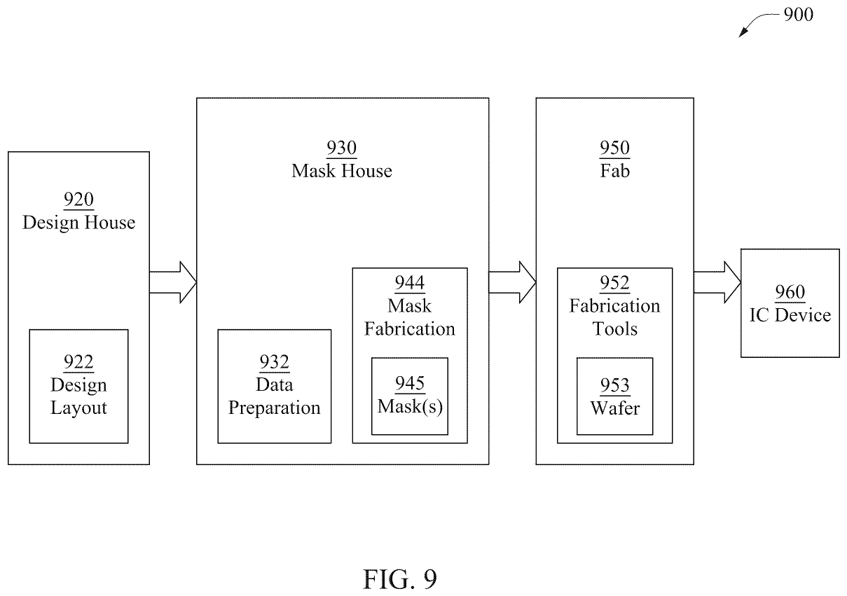

The method 600 is implementable, for example, using an electronic design automation (EDA) system 800 described below in connection with FIG. 8 and an integrated circuit (IC) manufacturing system 900 discussed below in connection with FIG. 9, in accordance with some embodiments. Regarding method 600, examples of the layout include the layouts 100, 300, 400, 500 disclosed herein.

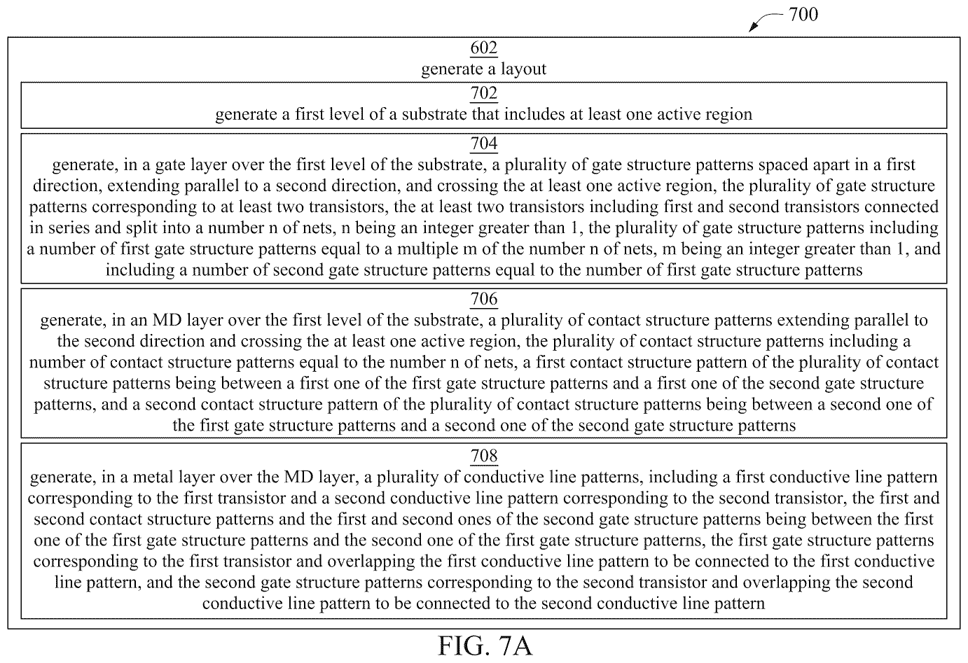

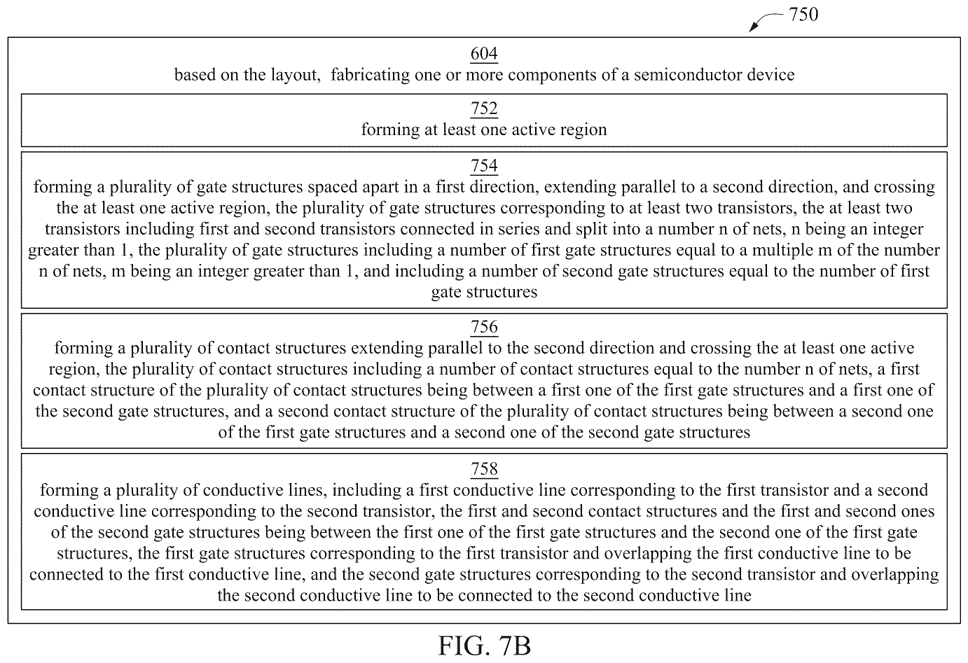

In FIG. 6, the method 600 includes blocks 602 and 604. At block 602, a layout is generated. The layout is one of the layouts 100, 300, 400, 500 disclosed herein, according to some embodiments. Block 602 is discussed in more detail below with respect to FIG. 7A. From block 602, flow proceeds to block 604.

At block 604, based on the layout, at least one of (A) one or more photolithographic exposures are made or (B) one or more semiconductor masks are fabricated or (C) one or more components in a layer of a semiconductor device are fabricated. See discussion below of FIG. 7B.

FIG. 7A is a flowchart of a method 700 of generating a layout, in accordance with some embodiments.

More particularly, the flowchart of FIG. 7A shows additional blocks that demonstrate an example of operations that may be implemented in block 602 of FIG. 6, in accordance with one or more embodiments.

In FIG. 7A, block 602 includes blocks 702, 704, 706, and 708.

At block 702, a first level of a substrate is generated in the layout to include at least one active region. In some embodiments, the at least one active region corresponds to a region in a layout that represents the active region 114 in FIG. 1, the active region 314 in FIG. 3, the active region 414 in FIG. 4, or the active region 514 in FIG. 5.

At block 704, a gate layer is generated over the first layer of the substrate to include a plurality of gate structure patterns spaced apart in a first direction, extending parallel to a second direction, and crossing the at least one active region, the plurality of gate structure patterns corresponding to at least two transistors, the at least two transistors including first and second transistors connected in series and split into a number n of nets, n being an integer greater than 1, the plurality of gate structure patterns including a number of first gate structure patterns equal to a multiple m of the number n of nets, m being an integer greater than 1, and including a number of second gate structure patterns equal to the number of first gate structure patterns. In some embodiments, the gate structure patterns correspond to regions in a layout that represent the gate structures 116 in FIG. 1, the gate structures 316 in FIG. 3, the gate structures 416 in FIG. 4, or the gate structures 516 in FIG. 5.

At block 706, an MD layer is generated over the first layer of the substrate to include a plurality of contact structure patterns extending parallel to the second direction and crossing the at least one active region, the plurality of contact structure patterns including a number of contact structure patterns equal to the number n of nets, a first contact structure pattern of the plurality of contact structure patterns being between a first one of the first gate structure patterns and a first one of the second gate structure patterns, and a second contact structure pattern of the plurality of contact structure patterns being between a second one of the first gate structure patterns and a second one of the second gate structure patterns. In some embodiments, the contact structure patterns correspond to regions in a layout that represent the contact structures 120 in FIG. 1, the contact structures 320 in FIG. 3, the contact structures 420 in FIG. 4, or the contact structures 520 in FIG. 5.

At block 708, a metal layer is generated over the MD layer to include a plurality of conductive line patterns, including a first conductive line pattern corresponding to the first transistor and a second conductive line pattern corresponding to the second transistor, the first and second contact structure patterns and the first and second ones of the second gate structure patterns being between the first one of the first gate structure patterns and the second one of the first gate structure patterns, the first gate structure patterns corresponding to the first transistor and overlapping the first conductive line pattern to be connected to the first conductive line pattern, and the second gate structure patterns corresponding to the second transistor and overlapping the second conductive line pattern to be connected to the second conductive line pattern. In some embodiments, the conductive line patterns correspond to regions in a layout that represent the conductive lines 104, 106 in FIG. 1, the conductive lines 304, 306 in FIG. 3, the conductive lines 404, 406 in FIG. 4, or the conductive lines 504, 506 in FIG. 5.

FIG. 7B is a flowchart of a method 750 of, based on the layout, fabricating one or more components of a semiconductor device, in accordance with some embodiments.

More particularly, the flowchart of FIG. 7B shows additional blocks that demonstrate an example of operations that may be implemented in block 604 of FIG. 6, in accordance with one or more embodiments.

In FIG. 7B, block 604 includes blocks 752, 754, 756, and 758.

At block 752, the method includes forming at least one active region. In some embodiments, the at least one active region corresponds to the active region 114 in FIG. 1, the active region 314 in FIG. 3, the active region 414 in FIG. 4, or the active region 514 in FIG. 5.

At block 754, the method includes forming a plurality of gate structures spaced apart in a first direction, extending parallel to a second direction, and crossing the at least one active region, the plurality of gate structures corresponding to at least two transistors, the at least two transistors including first and second transistors connected in series and split into a number n of nets, n being an integer greater than 1, the plurality of gate structures including a number of first gate structures equal to a multiple m of the number n of nets, m being an integer greater than 1, and including a number of second gate structures equal to the number of first gate structures. In some embodiments, the gate structures correspond to the gate structures 116 in FIG. 1, the gate structures 316 in FIG. 3, the gate structures 416 in FIG. 4, or the gate structures 516 in FIG. 5, and the first and second transistors correspond to MOS_A and MOS_B of FIGS. 1, 2A-2D, and 3-5.

At block 756, the method includes forming a plurality of contact structures extending parallel to the second direction and crossing the at least one active region, the plurality of contact structures including a number of contact structures equal to the number n of nets, a first contact structure of the plurality of contact structures being between a first one of the first gate structures and a first one of the second gate structures, and a second contact structure of the plurality of contact structures being between a second one of the first gate structures and a second one of the second gate structures. In some embodiments, the contact structures correspond to the contact structures 120 in FIG. 1, the contact structures 320 in FIG. 3, the contact structures 420 in FIG. 4, or the contact structures 520 in FIG. 5.

The described methods include example operations, but they are not necessarily required to be performed in the order shown and/or described. Operations may be added, replaced, changed order, and/or eliminated as appropriate, in accordance with the spirit and scope of embodiments of the disclosure. Embodiments that combine different features and/or different embodiments are within the scope of the disclosure and will be apparent to those of ordinary skill in the art after reviewing this disclosure.

In some embodiments, at least one method discussed above is performed in whole or in part by at least one EDA system. In some embodiments, the EDA system is usable as part of a design house of an IC manufacturing system discussed below.

FIG. 8 is a block diagram of an EDA system 800 in accordance with some embodiments. The EDA system 800 is configured to generate a layout as described above with respect to FIG. 7A.

In some embodiments, the EDA system 800 includes an automated place and route (APR or APnR) system. Methods described herein of designing layouts that represent wire routing arrangements, in accordance with one or more embodiments, are implementable using the EDA system 800, in accordance with some embodiments.

In some embodiments, the EDA system 800 is a general purpose computing device including at least one hardware processor 802 and a non-transitory, computer-readable storage medium 804. The computer-readable storage medium 804, amongst other things, is encoded with, i.e., stores, computer program code 806, i.e., a set of computer-executable instructions. Execution of the instructions 806 by the processor 802 represents (at least in part) an EDA tool that implements a portion or all of the methods described herein in accordance with one or more embodiments (which may be referred to herein as the noted processes and/or methods).

The processor 802 is electrically coupled to the computer-readable storage medium 804 via a bus 808. The processor 802 is also electrically coupled to an I/O interface 810 by the bus 808. A network interface 812 is also electrically connected to the processor 802 via the bus 808. The network interface 812 may be connected to a network 814, so that the processor 802 and the computer-readable storage medium 804 can connect to external elements via the network 814. The processor 802 is configured to execute computer program code 806 (instructions) encoded in (or stored in) the computer-readable storage medium 804 in order to cause EDA system 800 to be usable for performing a portion or all of the noted processes and/or methods. In some embodiments, the processor 802 is a central processing unit (CPU), a multi-processor, a distributed processing system, an application specific integrated circuit (ASIC), and/or a suitable processing unit.

In some embodiments, the computer-readable storage medium 804 is an electronic, magnetic, optical, electromagnetic, infrared, and/or a semiconductor system (or apparatus or device). In some embodiments, the computer-readable storage medium 804 includes a semiconductor or solid-state memory, a magnetic tape, a removable computer diskette, a random access memory (RAM), a read-only memory (ROM), a rigid magnetic disk, and/or an optical disk. In some embodiments using optical disks, the computer-readable storage medium 804 includes a compact disk-read only memory (CD-ROM), a compact disk-read/write (CD-R/W) memory, and/or a digital video disc (DVD) memory.

In some embodiments, the computer-readable storage medium 804 stores computer program code 806 configured to cause the EDA system 800 (where such execution represents (at least in part) the EDA tool) to be usable for performing a portion or all of the noted processes and/or methods. In some embodiments, the computer-readable storage medium 804 also stores information that facilitates performing a portion or all of the noted processes and/or methods. In some embodiments, the computer-readable storage medium 804 stores a library 807 of standard cells, which represent or include one or more of the layouts disclosed herein.

The EDA system 800 includes the I/O interface 810. The I/O interface 810 is coupled to external circuitry or controls such as a keyboard, keypad, mouse, trackball, trackpad, touchscreen, and/or cursor direction keys for communicating information and commands to processor 802.

The EDA system 800 also includes the network interface 812 coupled to processor 802. The network interface 812 allows the EDA system 800 to communicate with the network 814, to which one or more other computer systems may be connected. In some embodiments, the network interface 812 includes wireless network interfaces such as BLUETOOTH, WIFI, WIMAX, GPRS, or WCDMA; or wired network interfaces such as ETHERNET, USB, or IEEE-1364. In some embodiments, a portion or all of noted processes and/or methods, is implemented in two or more of the EDA systems 800.

The EDA system 800 is configured to receive information through the I/O interface 810. The information received through the I/O interface 810 includes one or more of instructions, data, design rules, libraries of standard cells, and/or other parameters for processing by the processor 802. The information is transferred to the processor 802 via the bus 808. The EDA system 800 is configured to receive information related to a user interface (UI) 842 through I/O interface 810. In some embodiments, the information stored in the computer-readable storage medium 804 encodes the UI 842.

In some embodiments, a portion or all of the noted processes and/or methods is implemented as a standalone software application for execution by a processor. In some embodiments, a portion or all of the noted processes and/or methods is implemented as a software application that is a part of an additional software application. In some embodiments, a portion or all of the noted processes and/or methods is implemented as a plug-in to a software application. In some embodiments, at least one of the noted processes and/or methods is implemented as a software application that is a portion of an EDA tool. In some embodiments, a portion or all of the noted processes and/or methods is implemented as a software application that is used by the EDA system 800. In some embodiments, a layout that includes standard cells is generated using a tool such as VIRTUOSO available from Cadence Design Systems, Inc., or another suitable layout generating tool.

In some embodiments, the processes are realized as functions of a program stored in a non-transitory, computer readable recording medium. Examples of such a computer readable recording medium include external/removable and/or internal/built-in storage or memory units, e.g., one or more of an optical disk, such as a DVD, a magnetic disk, such as a hard disk, a semiconductor memory, such as a ROM, a RAM, a memory card, and the like.

FIG. 9 is a block diagram of an IC manufacturing system 900, and an IC manufacturing flow associated therewith, in accordance with some embodiments. The IC manufacturing system 900 is configured to manufacture a semiconductor device or integrated circuit according to embodiments described herein.

In some embodiments, based on a layout, e.g., at least one of (A) one or more semiconductor masks or (B) at least one component in a layer of a semiconductor integrated circuit is fabricated using the IC manufacturing system 900.

In FIG. 9, the IC manufacturing system 900 includes entities, such as a design house 920, a mask house 930, and an IC manufacturer/fabricator (“fab”) 950, that interact with one another in the design, development, and manufacturing cycles and/or services related to manufacturing an IC device 960. The entities in the IC manufacturing system 900 are connected by a communications network. In some embodiments, the communications network is a single network. In some embodiments, the communications network is a variety of different networks, such as an intranet and the Internet. In some embodiments, the communications network includes wired and/or wireless communication channels. In some embodiments, each entity interacts with one or more of the other entities, and provides services to and/or receives services from one or more of the other entities. In some embodiments, two or more of the design house 920, the mask house 930, and the IC fab 950 are owned by a single larger company. In some embodiments, two or more of the design house 920, the mask house 930, and the IC fab 950 coexist in a common facility and use common resources.

The design house (or design team) 920 generates an IC design layout 922. The IC design layout 922 includes various geometrical patterns designed for the IC device 960. The geometrical patterns correspond to patterns of, e.g., metal, oxide, or semiconductor layers that make up the various components of the IC device 960 to be fabricated. The various layers combine to form various IC features. For example, a portion of the IC design layout 922 includes various IC features, such as an active region, gate electrode, source and drain, metal lines or vias of an interlayer interconnection, and openings for bonding pads, to be formed in a semiconductor substrate (such as a silicon wafer) and various material layers disposed on the semiconductor substrate. In some embodiments, the design house 920 implements a formal design procedure to form the IC design layout 922. In some embodiments, the design procedure includes one or more of logic design, physical design, or place and route. In some embodiments, the IC design layout 922 is presented in one or more data files having information of the geometrical patterns. For example, IC design layout 922 can be expressed in a GDSII file format or DFII file format.

The mask house 930 includes mask data preparation 932 and mask fabrication 944. The mask house 930 uses the IC design layout 922 to manufacture one or more masks 945 to be used for fabricating various layers of the IC device 960 according to the IC design layout 922. The mask house 930 performs mask data preparation 932, where the IC design layout 922 is translated into a representative data file (RDF). The mask data preparation 932 provides the RDF to the mask fabrication 944. In some embodiments, the mask fabrication 944 includes a mask writer. The mask writer converts the RDF to an image on a substrate, such as a mask (reticle) 945 or a semiconductor wafer 953. The IC design layout 922 is manipulated by mask data preparation 932 to comply with particular characteristics of the mask writer and/or requirements of the IC fab 950. In FIG. 9, the mask data preparation 932 and the mask fabrication 944 are illustrated as separate elements. In some embodiments, the mask data preparation 932 and the mask fabrication 944 can be collectively referred to as mask data preparation.

In some embodiments, the mask data preparation 932 includes optical proximity correction (OPC), which uses lithography enhancement techniques to compensate for image deviations, such as those that can arise from diffraction, interference, other process effects and the like. The OPC adjusts the IC design layout 922. In some embodiments, the mask data preparation 932 includes further resolution enhancement techniques (RET), such as off-axis illumination, sub-resolution assist features, phase-shifting masks, other suitable techniques, and the like, or combinations thereof. In some embodiments, inverse lithography technology (ILT) is also used, which treats OPC as an inverse imaging problem.

In some embodiments, the mask data preparation 932 includes a mask rule checker (MRC) that checks the IC design layout 922 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout 922 to compensate for limitations during the mask fabrication 944, which may undo part of the modifications performed by OPC in order to meet mask creation rules.

In some embodiments, the mask data preparation 932 includes lithography process checking (LPC) that simulates processing that will be implemented by the IC fab 950 to fabricate the IC device 960. In some embodiments, the LPC simulates this processing based on the IC design layout 922 to create a simulated manufactured device corresponding to the IC device 960. The processing parameters in the LPC simulation can include parameters associated with various processes of the IC manufacturing cycle, parameters associated with tools used for manufacturing the IC device 960, and/or other aspects of the manufacturing process. In some embodiments, the LPC takes into account factors such as aerial image contrast, depth of focus (DOF), mask error enhancement factor (MEEF), or the like, or combinations thereof. In some embodiments, after a simulated manufactured device has been created by the LPC, if the simulated device is not close enough in shape to satisfy design rules, OPC and/or MRC are be repeated to further refine the IC design layout 922.

The above description of mask data preparation 932 has been simplified for the purposes of clarity. In some embodiments, the mask data preparation 932 includes additional features such as a logic operation (LOP) to modify the IC design layout 922 according to manufacturing rules. Additionally, the processes applied to the IC design layout 922 during the mask data preparation 932 may be executed in a variety of different orders.

After the mask data preparation 932 and during the mask fabrication 944, a mask 945 or a group of masks 945 are fabricated based on the modified IC design layout 922. In some embodiments, the mask fabrication 944 includes performing one or more lithographic exposures based on the IC design layout 922. In some embodiments, an electron-beam (e-beam) or a mechanism of multiple e-beams is used to form a pattern on the mask (photomask or reticle) 945 based on the modified IC design layout 922. The mask 945 can be formed in various technologies. In some embodiments, the mask 945 is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In an example, a binary mask version of the mask 945 includes a transparent substrate (e.g., fused quartz) and an opaque material (e.g., chrome) coated in the opaque regions of the binary mask. In another example, the mask 945 is formed using a phase shift technology. In a phase shift mask (PSM) version of the mask 945, various features in the pattern formed on the phase shift mask are configured to have proper phase difference to enhance the resolution and imaging quality. In some embodiments, the phase shift mask is an attenuated PSM or an alternating PSM. The mask(s) generated by the mask fabrication 944 can be used in a variety of processes. For example, the mask(s) can be used in an ion implantation process to form various doped regions in a semiconductor wafer 953, in an etching process to form various etching regions in the semiconductor wafer 953, and/or in other suitable processes.

The IC fab 950 is an IC fabrication business that includes one or more manufacturing facilities for the fabrication of a variety of different IC products. In some embodiments, the IC fab 950 is a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (back-end-of-line (BEOL) fabrication), and a third manufacturing facility may provide other services for the foundry business.

The IC fab 950 includes fabrication tools 952 configured to execute various manufacturing operations on the semiconductor wafer 953 such that the IC device 960 is fabricated in accordance with the mask(s), e.g., the mask 945. In some embodiments, the fabrication tools 952 include one or more of a wafer stepper, an ion implanter, a photoresist coater, a process chamber, e.g., a CVD chamber or LPCVD furnace, a CMP system, a plasma etch system, a wafer cleaning system, or other manufacturing equipment capable of performing one or more suitable manufacturing processes as discussed herein.

The IC fab 950 uses the mask(s) 945 fabricated by the mask house 930 to fabricate the IC device 960. Thus, the IC fab 950 at least indirectly uses the IC design layout 922 to fabricate the IC device 960. In some embodiments, the semiconductor wafer 953 is fabricated by the IC fab 950 using the mask(s) 945 to form the IC device 960. In some embodiments, the IC fabrication includes performing one or more lithographic exposures based at least indirectly on the IC design layout 922. In some embodiments, the semiconductor wafer 953 includes a silicon substrate or other suitable substrate, which may have material layers formed thereon. In some embodiments, the semiconductor wafer 953 includes one or more of various doped regions, dielectric features, multilevel interconnects, or the like (which may be formed at subsequent manufacturing steps).

Details regarding an integrated circuit (IC) manufacturing system (e.g., the IC manufacturing system 900 of FIG. 9), and an IC manufacturing flow associated therewith are found, e.g., in U.S. Pat. No. 9,256,709, granted Feb. 9, 2016, U.S. Pre-Grant Publication No. 2015/0278429 A1, published Oct. 1, 2015, U.S. Pre-Grant Publication No. 2014/0040838 A1, published Feb. 6, 2014, and U.S. Pat. No. 7,260,442, granted Aug. 21, 2007, the entireties of each of which are hereby incorporated by reference.

An aspect of this disclosure relates to an integrated circuit (IC) device. In some embodiments, an integrated circuit (IC) device includes an active region; a first conductive line extending in a first direction and corresponding to a first transistor, and a second conductive line extending in the first direction and corresponding to a second transistor, the first and second transistors being connected in series and split into two or more nets; first gate structures connected to the first conductive line and corresponding to the first transistor, the first gate structures being spaced apart in the first direction and extending in a second direction; second gate structures connected to the second conductive line and corresponding to the second transistor, a number of the second gate structures being equal to the number of first gate structures; and a first contact structure between a first one of the first gate structures and a first one of the second gate structures, and a second contact structure between a second one of the first gate structures and a second one of the second gate structures, the number of contact structures being equal to the number of nets.

Another aspect of this disclosure relates to a method of manufacturing an integrated circuit (IC) device. In some embodiments, a method of manufacturing an integrated circuit (IC) device includes forming an active region; forming first gate structures corresponding to a first transistor, the first gate structures being spaced apart in a first direction and extending in a second direction; forming second gate structures corresponding to a second transistor, the second gate structures being formed in a number equal to the number of first gate structures; forming a first contact structure between a first one of the first gate structures and a first one of the second gate structures; forming a second contact structure between a second one of the first gate structures and a second one of the second gate structures; forming a first conductive line extending in the first direction and connected to the first gate structures, and corresponding to the first transistor; and forming a second conductive line extending in the first direction and connected to the second gate structures, and corresponding to the second transistor. The first and second transistors are formed to be connected in series and split into two or more nets, and the contact structures are formed in a number equal to the number of nets.

Another aspect of this disclosure relates to an integrated circuit (IC) device. In some embodiments, an integrated circuit (IC) device includes an active region; gate structures crossing the active region, the gate structures including: first gate structures corresponding to a first transistor, the first gate structures being spaced apart in a first direction and extending in a second direction, and second gate structures corresponding to a second transistor, the second gate structures being equal in number to the first gate structures, the first and second transistors being connected in series and split into two or more nets; contact structures crossing the active region, the contact structures including: a first contact structure between a first one of the first gate structures and a first one of the second gate structures, and a second contact structure between a second one of the first gate structures and a second one of the second gate structures, the contact structures being equal in number to the number of nets; a first conductive line extending in the first direction and connected to the first gate structures, and corresponding to the first transistor; and a second conductive line extending in the first direction and connected to the second gate structures, and corresponding to the second transistor.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit (IC) device comprising:
an active region;
a first conductive line extending in a first direction and corresponding to a first transistor, and a second conductive line extending in the first direction and corresponding to a second transistor, the first and second transistors being connected in series and split into two or more nets;
first gate structures connected to the first conductive line and corresponding to the first transistor, the first gate structures being spaced apart in the first direction and extending in a second direction;
second gate structures connected to the second conductive line and corresponding to the second transistor, a number of the second gate structures being equal to the number of first gate structures; and
a first contact structure between a first one of the first gate structures and a first one of the second gate structures, and a second contact structure between a second one of the first gate structures and a second one of the second gate structures, the number of contact structures being equal to the number of nets.

2. The IC device of claim 1, wherein the active region is an N-type active region, and the first and second transistors are NMOS transistors.

3. The IC device of claim 1, wherein the active region is a P-type active region, and the first and second transistors are PMOS transistors.

4. The IC device of claim 1, wherein the first and second contact structures and the first and second ones of the second gate structures are between the first one of the first gate structures and the second one of the first gate structures.

5. The IC device of claim 1, wherein the first and second gate structures are arranged in a cell region of the IC in a sequence ‘ABBA’ in the first direction, in which the first and second ones of the first gate structures are fingers ‘A’ of the first transistor and the first and second ones of the second gate structures are fingers ‘B’ of the second transistor.

6. The IC device of claim 5, wherein the sequence ‘ABBA’ is repeated a number i times in the cell region, i being an integer greater than 0, and each of the first and second transistors has a number of fingers equal to 4i.

7. The IC device of claim 6, comprising a number 4i of the contact structures extending parallel to the second direction and crossing the active region.

8. The IC device of claim 1, wherein the first and second gate structures are arranged in a cell region of the IC and, in the cell region, outermost gate structures correspond to a same one of the first and second transistors.

9. The IC device of claim 1, wherein the first and second contact structures are free of vias in a via layer that is over the first and second contact structures and under an overlying metal layer that includes the first and second conductive lines.

10. A method of manufacturing an integrated circuit (IC) device, the method comprising:
forming an active region;
forming first gate structures corresponding to a first transistor, the first gate structures being spaced apart in a first direction and extending in a second direction;
forming second gate structures corresponding to a second transistor, the second gate structures being formed in a number equal to the number of first gate structures;
forming a first contact structure between a first one of the first gate structures and a first one of the second gate structures;
forming a second contact structure between a second one of the first gate structures and a second one of the second gate structures;
forming a first conductive line extending in the first direction and connected to the first gate structures, and corresponding to the first transistor; and
forming a second conductive line extending in the first direction and connected to the second gate structures, and corresponding to the second transistor,
wherein:
the first and second transistors are formed to be connected in series and split into two or more nets, and
the contact structures are formed in a number equal to the number of nets.

11. The method of claim 10, wherein the forming the active region includes forming an N-type active region, and the first and second transistors are NMOS transistors.

12. The method of claim 10, wherein the forming the active region includes forming a P-type active region, and the first and second transistors are PMOS transistors.

13. The method of claim 10, wherein the forming the first and second contact structures and the first and second ones of the second gate structures includes:
forming the first and second contact structures and the first and second ones of the second gate structures to be between the first one of the first gate structures and the second one of the first gate structures.

14. The method of claim 10, wherein the first and second gate structures are formed in a cell region of the IC device in a sequence ‘ABBA’ in the first direction, in which the first and second ones of the first gate structures are fingers ‘A’ of the first transistor and the first and second ones of the second gate structures are fingers ‘B’ of the second transistor.

15. The method of claim 14, wherein the first and second gate structures are formed such that the sequence ‘ABBA’ is repeated a number i times in the cell region, i being an integer greater than 0, and each of the first and second transistors has a number of fingers equal to 4i.

16. The method of claim 15, wherein the forming the first and second contact structures includes forming a number 4i of contact structures extending parallel to the second direction and crossing the active region.

17. The method of claim 10, wherein the first and second gate structures are formed in a cell region of the IC and, in the cell region, outermost gate structures correspond to a same one of the first and second transistors.

18. The method of claim 10, wherein the first and second contact structures are formed to be free of vias in a via layer that is over an MD layer that includes the first and second contact structures and under a metal layer that includes the first and second conductive lines.

19. A semiconductor device comprising:
an active region;
gate structures crossing the active region, the gate structures including:
first gate structures corresponding to a first transistor, the first gate structures being spaced apart in a first direction and extending in a second direction, and
second gate structures corresponding to a second transistor, the second gate structures being equal in number to the first gate structures,
the first and second transistors being connected in series and split into two or more nets;
contact structures crossing the active region, the contact structures including:
a first contact structure between a first one of the first gate structures and a first one of the second gate structures, and
a second contact structure between a second one of the first gate structures and a second one of the second gate structures,
the contact structures being equal in number to the number of nets;
a first conductive line extending in the first direction and connected to the first gate structures, and corresponding to the first transistor; and
a second conductive line extending in the first direction and connected to the second gate structures, and corresponding to the second transistor.

20. The semiconductor device of claim 19, wherein the first transistor is the same conductivity type as the second transistor.
